(19) United States
(12) Patent Application Publication
(10) Pub. No.: US 2024/0429098 A1
(43) Pub. Date: Dec. 26, 2024

(54) MERGED SELF-ALIGNED BACKSIDE CONTACT

(71) Applicant: International Business Machines Corporation, Armonk, NY (US)

(72) Inventors: Albert M. Chu, Nashua, NH (US); Ruilong Xie, Niskayuna, NY (US); Brent A. Anderson, Jericho, VT (US); Junli Wang, Slingerlands, NY (US); Jay William Strane, Wappingers Falls, NY (US); Leon Sigal, Monsey, NY (US); David Wolpert, Poughkeepsie, NY (US)

(21) Appl. No.: 18/340,301

(22) Filed: Jun. 23, 2023

(51) Int. Cl. H01L 21/768; H01L 21/74; H01L 21/8234; H01L 23/528; H01L 23/535; H01L 29/06

(52) U.S. Cl. CPC H01L 21/76897; H01L 21/743; H01L 21/823475; H01L 23/5286; H01L 23/535; H01L 29/0673

(57) ABSTRACT

A semiconductor structure with two adjacent semiconductor devices of a plurality of semiconductor devices that have a backside contact that connects two adjacent source/drains of the two adjacent semiconductor devices to a backside power rail. The semiconductor provides the backside contact with a larger bottom contact area with the backside power rail than a combined contact area of the two top surfaces of the backside contact with the two adjacent source/drains.

### BACKGROUND

The disclosure generally relates to forming a semiconductor device and more particularly, to forming nanosheet field-effect transistors with a merged backside contact.

The amount of data we process is rapidly increasing at a rate higher than that of Moore's law. Increasing system performance requirements, driven at least in part by the increasing use of artificial intelligence, continue to drive tighter pitches in semiconductor devices and smaller semiconductor chips. For logic scaling at the two-nanometer node, planar and non-planar semiconductor device structures, such as metal-oxide-semiconductor field-effect transistors (MOSFETs), must be scaled to smaller dimensions.

With evolution of reduced-size transistors, semiconductor technology has progressed from planar transistor designs to three-dimensional type finFET designs which are further evolving into gate-all-around transistor designs. With increasing demands to reduce the dimensions of transistor devices, nanosheet field-effect transistors (FETs) help achieve a reduced device footprint while maintaining device performance. A nanosheet FET device contains one or more portions of layers of semiconductor channel material having a vertical thickness that is substantially less than its width. A typical nanosheet FET includes a plurality of stacked nanosheets extending between a pair of source/drain epitaxial regions. The nanosheet FET device may be a gate-all-around device in which a gate surrounds the channels of the nanosheet FET devices. Utilizing stacked nanosheets, Gate-All-Around nanosheet field-effect transistors (GAA nanosheet FETs) and 3D-stacked complementary metal-oxide semiconductor (CMOS) devices such as complementary field-effect transistor devices will be the key to continuing to extend beyond Moore's Law.

GAA nanosheet (or nanowire) FET devices are a viable option for continued device scaling. GAA nanosheet FET devices have been recognized as excellent candidates to achieve improved power performance and area scaling compared to FinFET technology. GAA nanosheet FET devices can provide high drive currents due to wide effective channel width (Weff) while maintaining short-channel control. However, in many cases, backside power delivery networks are needed to be coupled with GAA nanosheet FETs for performance and back-end-of-line (BEOL) wiring congestion issues.

As the semiconductor industry continues to drive to the two-nanometer technology node with tighter pitches and increasing performance, increased use of backside interconnect layers for a backside power delivery network is emerging. Creating backside interconnect layers below the front-end-of-line semiconductor devices provides improved power performance and more routing options for semiconductor devices relieving some of the BEOL wiring congestion. Utilizing a backside power delivery network can enable ten to thirty-five percent logic area scaling reduction in a two-nanometer technology node that utilizes GAA nanosheet FETs. A backside power delivery network improves semiconductor device gate delay and reduces BEOL wiring congestion.

### SUMMARY

The following presents a summary to provide a basic understanding of one or more embodiments of the disclosure. This summary is not intended to identify key elements or delineate any scope of the particular embodiments or any scope of the claims.

Aspects of the disclosed invention relate to a semiconductor structure including two adjacent semiconductor devices of a plurality of semiconductor devices and a backside contact connecting two adjacent source/drains of the two adjacent semiconductor devices to a backside power rail. The semiconductor structure of embodiments of the present invention provides the backside contact with a larger bottom contact area with the backside power rail than a combined top contact area of the two top surfaces of the backside contact with the two adjacent source/drains. The two adjacent source/drains are separated by a single diffusion break that resides above a central portion of the backside contact.

Additionally, embodiments of the present invention provide a semiconductor structure with two adjacent semiconductor devices and a backside contact that connects one source/drain connected to the two adjacent semiconductor devices to a backside power rail. The bottom surface of the backside contact is larger than the top surface of the backside contact contacting the source/drain. The semiconductor structure provides the bottom surface of the backside contact with a width that is equal to approximately one contacted gate pitch. The inner spacers of the two adjacent gates contact the source/drain connecting to the backside contact. The semiconductor structure includes the backside contact that has a flattened cone shape with a wider bottom surface on the backside power rail and a smaller top surface contacting the source/drain.

Embodiments of the present invention provide a method of forming a semiconductor structure that includes forming a plurality of dummy gates with a hardmask on a plurality of nanosheet stacks. The method includes removing the bottom sacrificial layer and depositing a layer of a dielectric material for a bottom dielectric isolation (BDI) on the semiconductor material layer. The method includes patterning a layer of an organic planarization layer and removing exposed portions of the BDI and a top portion of the semiconductor material. The method includes etching portions of the semiconductor material adjacent to the top portion of the semiconductor conductor material removed under the removed BDI and then, removing the organic planarization layer. Furthermore, the method includes growing two placeholder elements by epitaxy, wherein each of the two placeholder elements are on an etch stop. In embodiments of the present invention, the method also includes forming a plurality of source/drains by epitaxy on each of the two placeholder elements. The method includes depositing a layer of interlayer dielectric material and planarizing.

The method includes patterning another organic planarization layer to remove exposed portions of the hardmask, the dummy gates under the hardmask, portions of the plurality of the channel layers under each dummy gate, and portions of the plurality of sacrificial layers under the portions of the plurality of channel layers. The method includes depositing a single diffusion barrier on an exposed portion of the BDI and performing a chemical-mechanical polish. The method includes removing each of the plurality of dummy gates with the hardmask followed by removing a portion each of the plurality of sacrificial layers and forming inner spacers. The method includes forming a replacement metal gate for a gate-all-around nanosheet FET and depositing another interlayer dielectric layer over the semiconductor structure. The method includes forming two contacts to two source/drains of the plurality of source/drains, wherein the two contacts connect to the two source/drains on the BDI and then, forming a back-end-of-line interconnect wiring. The method includes bonding a carrier wafer to the back-end-of-line interconnect wiring and removing the substrate exposing the etch stop and then, removing the etch stop. The method includes removing the semiconductor material and depositing a backside interlayer dielectric and planarizing. The method includes removing the two placeholder elements and depositing a backside contact material and planarizing semiconductor structure to remove excess backside contact material. The method includes forming a backside power rail contacting the backside ILD and the backside contact material on a top surface. Furthermore, the method includes forming a backside power delivery network connecting to a bottom surface of the backside power rail.

### BRIEF DESCRIPTION OF THE DRAWINGS

The above and other aspects, features, and advantages of various embodiments of the present invention will be more apparent from the following description taken in conjunction with the accompanying drawings.

FIG. 1 depicts a top view of a semiconductor design of dummy gates on a nanosheet stack, in accordance with an embodiment of the present invention.

FIG. 2 depicts a cross-sectional view of a semiconductor structure after forming a dummy gate on the nanosheet stack, in accordance with an embodiment of the present invention.

FIG. 3 depicts a cross-sectional view of the semiconductor structure after removing the bottom sacrificial layer and forming sidewall spacers on the dummy gates, in accordance with an embodiment of the present invention.

FIG. 4 depicts a cross-sectional view of the semiconductor structure after removing portions of the nanosheet stack and forming inner spacers, in accordance with an embodiment of the present invention.

FIG. 5 depicts a cross-sectional view of the semiconductor structure after forming a liner around the sidewalls of the dummy gate and remaining portions of the nanosheet stack, in accordance with an embodiment of the present invention.

FIG. 6 depicts a top view of the semiconductor structure after depositing and patterning an organic planarization layer (OPL), in accordance with an embodiment of the present invention.

FIG. 7 depicts a cross-sectional view of the semiconductor after forming cavities in the semiconductor substrate below the bottom dielectric isolation (BDI) for the backside contacts, in accordance with an embodiment of the present invention.

FIG. 8 depicts a cross-sectional view of the semiconductor structure after removing the OPL and growing by epitaxy the placeholder material in each of the two cavities for two placeholder elements, in accordance with an embodiment of the present invention.

FIG. 9 depicts a cross-sectional view of the semiconductor structure after removing the protective liner on the dummy gates and growing the source/drain (S/D), in accordance with an embodiment of the present invention.

FIG. 10 depicts a cross-sectional view of the semiconductor structure after depositing an interlayer dielectric (ILD) and performing a chemical mechanical polish (CMP), in accordance with an embodiment of the present invention.

FIG. 11 depicts a cross-sectional view of the semiconductor structure after depositing and patterning another layer of OPL and removing the exposed hardmask, dummy gate, channel layers, and sacrificial layers under the removed portion of the hardmask, in accordance with an embodiment of the present invention.

FIG. 12 depicts a cross-sectional view of the semiconductor structure after depositing a dielectric material and performing a CMP, in accordance with an embodiment of the present invention.

FIG. 13 depicts a cross-sectional view of the semiconductor structure after replacement metal gate formation, contact formation, backend-of-line (BEOL) interconnect wiring formation, and carrier wafer bonding, in accordance with an embodiment of the present invention.

FIG. 14 depicts a cross-sectional view of the semiconductor structure after wafer flip and substrate removal, in accordance with an embodiment of the present invention.

FIG. 15 depicts a cross-sectional view of the semiconductor structure after etch stop removal, in accordance with an embodiment of the present invention.

FIG. 16 depicts a cross-sectional view of the semiconductor structure after removing exposed portions of the silicon layer, in accordance with an embodiment of the present invention.

FIG. 17 depicts a cross-sectional view of the semiconductor structure after depositing a backside ILD, in accordance with an embodiment of the present invention.

FIG. 18 depicts the cross-sectional view of the semiconductor structure after removing the placeholder material, in accordance with an embodiment of the present invention.

FIG. 19 depicts a cross-sectional view of the semiconductor structure after forming the backside contacts, the backside power rail, and the backside power delivery network (BSPDN), in accordance with an embodiment of the present invention.

FIG. 20 depicts a top view of a semiconductor design of a nanosheet semiconductor device with a merged backside contact and an enlarged backside contact, in accordance with an embodiment of the present invention.

### DETAILED DESCRIPTION

According to an aspect of the invention, a semiconductor structure is provided with two adjacent semiconductor devices of a plurality of semiconductor devices, two adjacent source/drains of the two adjacent semiconductor devices, and a backside contact that connects the two adjacent source/drains of the two adjacent semiconductor devices to a backside power rail. The backside contact receives current from each of the two adjacent source/drains. The two adjacent semiconductor devices are separated by a single diffusion break. The backside contact provides a large contact surface with the backside power rail to reduce the voltage drop to the power distribution network which results in improved electrical performance of the two adjacent semiconductor devices.

In embodiments, the backside contact has a larger bottom contact area with the backside power rail than a combined area of the two top surfaces of the backside contact connecting with the two adjacent source/drains. In this way, the backside contact with a large bottom contact area connecting to the backside power rail reduces the electrical resistance and thermal resistance of the connection of the backside contact to the backside power rail. More specifically, in embodiments, the backside contact has a the bottom surface contact area with the backside power rail where the bottom surface contact area has a width of approximately two contacted gate pitches. The two contacted gate pitches occur, approximately, along a centerline between the centers of the two adjacent source/drains contacting the backside contact. Providing the backside contact with a large bottom surface contact area with the backside power rail reduces the resistance of the connection of the backside contact to the backside power rail.

Furthermore, in embodiments, the backside contact connects the two adjacent source/drains of the two adjacent semiconductor devices to the backside power rail by two top surfaces of the backside contact. Each top surface of the two top surfaces of the backside contact connect to a source/drain of the two adjacent source/drains. Each top surface of the backside contact receives a device current from one source/drain of the two adjacent source/drains. The backside contact extends downward to create a single, large bottom surface of the backside contact connecting to the backside power rail.

Additionally, in embodiments, the backside contact joins the electrical current, received by the two top surfaces of the backside contact, and provides the electrical current of the two adjacent source/drains of the two adjacent semiconductor devices through the bottom surface of the backside contact to the backside power rail. The bottom surface of the backside contact connecting to the backside power rail has a large contact area with a length of about two contact gate pitches. Providing the large contact area of the bottom of the backside contact with the backside power rail reduces the voltage drop to the power distribution network, reduces the IR drop, increases the effective channel length (Ieff), and thereby improves semiconductor device performance. By merging the top two surfaces of the backside contact into one large backside contact bottom contact area, the electrical resistance of the backside contact to the backside power rail is reduced when compared to a smaller conventional backside contact connection to the backside power rail.

In embodiments, the backside contact has a sidewall that has an angle between 40 and 80 degrees with a surface of the backside power rail. The sloped sidewall of the backside contact provides the large contact area of the bottom surface of the backside contact that increases the electrical performance of the two adjacent semiconductor devices by reducing the electrical resistance of the connection between the backside contact with the backside power rail.

In embodiments, the backside contact includes a portion of a semiconductor material below and between the two adjacent source/drains. The portion of the semiconductor material is directly contacting a bottom dielectric isolation layer and is below, at least, a portion of the single diffusion break. The portion of the semiconductor material resides between the two top surfaces of the backside contact that connect to each source/drain of the two adjacent source/drains. The portion of the semiconductor material has an upside-down cone-like wedge shape. With the portion of the semiconductor material between the two top surfaces, the backside contact has an M-shape in a cross-sectional view where the two top surfaces of the M each contact a source/drain, and the open bottom portion of the M contacts the backside power rail. The M-shaped cross-sectional view of the backside contact can also be considered a cross-sectional view of two adjacent and connected mountains. The M-shaped cross-sectional view of the backside illustrates the large contact area of the bottom portion of the backside contact with the backside power rail which reduces the resistance of the connection between the backside contact and the backside power rail resulting in improved electrical performance of the two adjacent semiconductor devices.

In embodiments, the space between a gate of the two semiconductor devices and the single diffusion break is less than the space between two adjacent gates of the other adjacent semiconductor devices that are not connected to the backside contact. In embodiments, the two adjacent source/drains have a distance between the two adjacent source/drains that is less than one contacted gate pitch where the contacted gate pitch is determined by the center-to-center pitch of the other semiconductor devices of the plurality of semiconductor devices not connected to the backside contact. Providing a smaller distance or space between the two adjacent source/drains increases the likelihood of merging the middle and bottom portion of the backside contact or just the bottom portion of the backside contact with the top portion of the backside contact connecting the two top surfaces to the two adjacent source/drains to the backside power rail.

In embodiments, the semiconductor structure with the two adjacent semiconductor devices of the plurality of semiconductor devices with the backside contact that connects two adjacent source/drains of the two adjacent semiconductor devices to the backside power rail also includes a contact that connects each of the two adjacent semiconductor devices to a back-end-of-line interconnect wiring layer bonded to a carrier wafer; a single diffusion break separating the two adjacent semiconductor devices; and a backside power delivery network that is directly under the backside power rail.

According to an aspect of the invention, a semiconductor structure is provided with two adjacent semiconductor devices, a source/drain that connects to the two adjacent semiconductor devices, and a backside contact that connects the source/drain to a backside power rail. The bottom surface of the backside contact contacting the backside power rail is larger than the top surface of the backside contact contacting the source/drain. The larger bottom surface of the backside contact reduces the electrical resistance of the backside contact connection to the backside power rail compared to a conventional backside contact with the backside power rail.

In embodiments, the bottom surface of the backside contact has a width of approximately one contacted gate pitch. Increasing the bottom surface of the backside contact that connects with the backside power rail reduces the resistance of the backside contact connection with the backside power rail and therefore, improves the electrical performance of the two adjacent semiconductor devices.

In embodiments, the backside contact has a flattened cone shape with a wider bottom surface on the backside power rail. The flattened cone shape creates the bottom surface of the backside contact with a larger width and a larger contact area of the backside contact with the backside power rail.

In embodiments, the backside contact has a sidewall that has an angle between 40 and 80 degrees with a surface of the backside power rail. Providing the sloped or angled contact of the backside contact with the surface of the backside power rail increases the size of the bottom surface of the backside contact in order to reduce the resistance of the connection between the backside contact and the backside power rail.

According to an aspect of the invention, a method of forming a semiconductor structure includes removing two portions of a bottom dielectric isolation layer and a top portion of a semiconductor material directly adjacent a liner covering a nanosheet stack, wherein the nanosheet stack is covered by a dummy gate. The method includes removing a second portion of the semiconductor material to increase a diameter of a cavity in the semiconductor material, wherein the removing the second portion of the semiconductor material stops at an etch stop layer. The method includes growing by epitaxy, a silicon-germanium material on the etch stop layer to fill the cavity in the semiconductor material and removing the liner. Furthermore, the method includes growing by epitaxy, two source/drains on the silicon-germanium material, wherein a top surface of the each of the two source/drains is above a top channel layer of the nanosheet stack. The method includes depositing an interlayer dielectric material and planarizing. The method includes removing the dummy gate and the nanosheet stack above a portion of the bottom dielectric isolation layer. Additionally, the method includes forming single diffusion break on the portion of the bottom dielectric isolation layer. The method includes removing a semiconductor substrate under the etch stop layer and then, removing the etch stop layer. The method includes removing the semiconductor material under the bottom dielectric isolation layer and depositing a backside interlayer dielectric material. Furthermore, the method includes removing the silicon-germanium material and forming a backside contact contacting the two source/drains. Forming the backside contact includes forming a width of a bottom surface of the backside that is wider than a combined width of the backside contact contacting the two source/drains. The backside contact is formed in the cavity and fills the cavity under the two source/drains and under adjacent portions of the bottom dielectric material layer. Further more, the method includes forming a backside power contacting the backside contact and the backside interlayer dielectric material.

In embodiments, forming single diffusion break on the portion of the bottom dielectric isolation layer also includes (1) removing the dummy gate and each layer of a sacrificial semiconductor material; (2) forming a replacement metal gate; (3) forming contacts to a back-end-line interconnect wiring; (4) attaching a carrier wafer; and (5) flipping the carrier wafer.

In embodiments, forming the backside contact contacting the two source/drains and the backside power rail includes forming the backside contact where a portion of the semiconductor material remains in the backside contact under the single diffusion break.

In optional embodiments, a method of forming a semiconductor structure includes forming a plurality of dummy gates with a hardmask on a plurality of nanosheet stacks, wherein each nanosheet stack includes a plurality of channel layers, a plurality of sacrificial layers on a bottom sacrificial layer directly on a layer of a semiconductor material above an etch stop that is on a substrate. The method includes removing the bottom sacrificial layer and depositing a layer of a dielectric material for a bottom dielectric isolation (BDI) on the semiconductor material layer. The method includes forming spacers on each of the plurality of dummy gates with the hardmask and removing portions of the plurality of sacrificial layers. The method includes forming inner spacers contacting each portion of the plurality of sacrificial layers remaining and, then conformally depositing a liner. The method includes performing a directional etch removing horizontal portions of the liner. The method includes patterning a layer of an organic planarization layer and removing exposed portions of the BDI and a top portion of the semiconductor material. The method includes etching portions of the semiconductor material adjacent to the top portion of the semiconductor conductor material removed under the removed BDI and then, removing the organic planarization layer. Furthermore, the method includes growing two placeholder elements by epitaxy, wherein each of the two placeholder elements are on an etch stop. Removing the liner occurs in the method. The method also includes forming a plurality of source/drains by epitaxy on each of the two placeholder elements. The method includes depositing a layer of interlayer dielectric material and planarizing.

The method includes patterning another organic planarization layer to remove exposed portions of a hardmask, a dummy gate under the hardmask, portions of the plurality of channel layers under the dummy gate, and portions of the plurality of sacrificial layers under the portions of the plurality of channel layers. The method includes depositing a single diffusion barrier on an exposed portion of the BDI and performing a chemical-mechanical polish. The method includes removing each of the plurality of dummy gates with the hardmask followed by removing each of the plurality of sacrificial layers. The method includes forming a replacement metal gate and depositing another interlayer dielectric layer over the semiconductor structure. The method includes forming two contacts to two source/drains of the plurality of source/drains, wherein the two contacts connect to the two source/drains on the BDI and then, forming a back-end-of-line interconnect wiring. The method includes bonding a carrier wafer to the back-end-of-line interconnect wiring and removing the substrate exposing the etch stop and then, removing the etch stop. The method includes removing the semiconductor material and depositing a backside interlayer dielectric and planarizing.

The method includes removing the two placeholder elements and depositing a backside contact material and planarizing semiconductor structure to remove excess backside contact material. The method includes forming a backside power rail contacting the backside ILD and the backside contact material on a top surface. Furthermore, the method includes forming a backside power delivery network connecting to the bottom surface of the backside power rail.

In some optional embodiments, the method includes depositing the backside contact material and planarizing which forms at least two backside contacts where a first backside contact of the two backside contacts connects one source/drain of the plurality of source/drains to the first backside power rail and a second backside contact connects two source/drains of the plurality of source/drains to the backside power rail. The method provides a larger contact area of each of the two backside contacts with the backside power rail to improve the semiconductor chip performance. The larger contact area of the backside contact with the backside power rail can improve both the electrical and thermal resistance of the backside contact connection with the backside power rail.

Some embodiments will be described in more detail with reference to the accompanying drawings, in which the embodiments of the present disclosure have been illustrated. However, the present disclosure can be implemented in various manners, and thus should not be construed to be limited to the embodiments disclosed herein.

It is to be understood that aspects of the present invention will be described in terms of a given illustrative architecture; however, other architectures, structures, substrate materials, process features, and steps can be varied within the scope of aspects of the present invention.

It will also be understood that when an element such as a layer, region, or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

Methods as described herein can be used in the fabrication of integrated circuit chips also known as a semiconductor chip. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher-level carrier) or in a multichip package (such as a ceramic carrier that has either or both surface interconnections or bottom interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

The terminology used herein is for the purpose of describing particular embodiments only and is not tended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

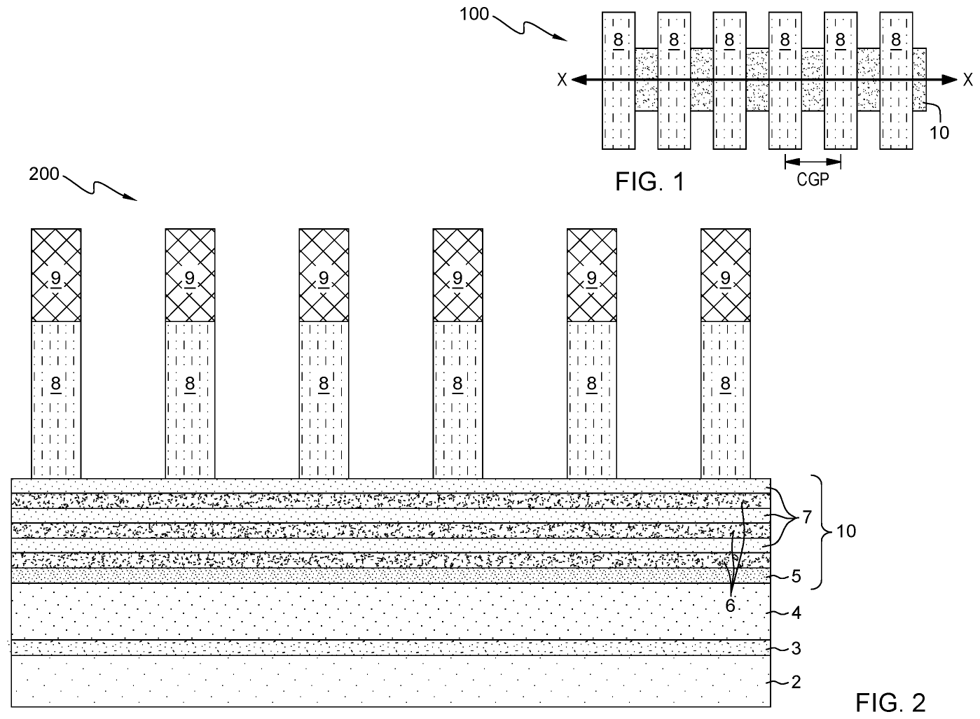

Spatially relative terms, such as “beneath,” “below,” “lower,” “above,” “upper,” and the like, can be used herein for ease of description to describe one element's or feature's relationship to another element(s) or feature(s) as illustrated in the FIGS. 1t will be understood that the spatially relative terms are intended to encompass different orientations of the device in use or operation in addition to the orientation depicted in the FIGS. For example, if the device in the FIGS. is turned over, elements described as “below,” or “beneath” other elements or features would then be oriented “above” the other elements or features. Thus, the term “below” can encompass both an orientation of above and below. The device can be otherwise oriented (rotated 90 degrees or at other orientations and the spatially relative descriptors used herein can be interpreted accordingly. In addition, be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Detailed embodiments of the claimed structures and methods are disclosed herein. The method steps described below do not form a complete process flow for manufacturing integrated circuits on semiconductor chips. The present embodiments can be practiced in conjunction with the integrated circuit fabrication techniques for semiconductor chips and devices currently used in the art, and only so much of the commonly practiced process steps are included as are necessary for an understanding of the described embodiments. The figures represent cross-section portions of a semiconductor chip or a substrate, such as a semiconductor wafer during fabrication, and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

Deposition processes for material, such as, the metal materials, dielectric materials, and sacrificial material include but are not limited to chemical vapor deposition (CVD), physical vapor deposition (PVD), atomic layer deposition (ALD), molecular layer deposition (MLD), high-density plasma (HDP) deposition, or gas cluster ion beam (GCIB) deposition. Variations of CVD processes include, but are not limited to, atmospheric pressure CVD (APCVD), low-pressure CVD (LPCVD), plasma enhanced CVD (PECVD), and metal-organic CVD (MOCVD), and combinations thereof may also be employed.

Removal, removing, or etching as used herein includes but is not limited to patterning using one of lithography, photolithography, an extreme ultraviolet (EUV) lithography process, or any other known semiconductor patterning process followed by one or more etching processes. Some examples of etching processes include but are not limited to the following processes, such as a dry etching process using a reactive ion etch (RIE) or ion beam etch (IBE), a wet chemical etch process, or a combination of these etching processes.

The terms “epitaxially growing and/or depositing” and “epitaxially grown and/or deposited” mean the growth of a semiconductor material on a deposition surface of a semiconductor material, which may be a seed semiconductor layer deposited on surface(s) of a semiconductor structure. The semiconductor material being grown has the same crystalline characteristics as the semiconductor material of the deposition surface. Examples of various epitaxial growth techniques include, for example, rapid thermal chemical vapor deposition (RTCVD), low-energy plasma deposition (LEPD), ultra-high vacuum chemical vapor deposition (UHVCVD), low-pressure chemical vapor deposition (LPCVD), atmospheric pressure chemical vapor deposition (APCVD) and molecular beam epitaxy (MBE).

It should also be understood that material compounds may be described in terms of listed elements, e.g., SiGe. These compounds include different proportions of the elements within the compound, e.g., SiGe includes SiₓGe₁₋ₓ where x is less than 1, etc. In addition, other elements can be included in the compound and still function in accordance with the present principles. The compounds with additional elements will be referred to herein as alloys.

As known by one skilled in the art, damascene processes for forming contacts and/or circuit lines typically include various steps of patterning of via holes and trenches in a dielectric material, such as an interlayer dielectric and filling the via holes and trenches with a layer of metal and planarizing the metal using a chemical mechanical process such as a chemical-mechanical polish (CMP) to remove overburden or excess metal.

Reference is now made to the figures. The figures provide schematic cross-sectional illustrations of semiconductor devices at intermediate stages of fabrication, according to one or more embodiments of the invention. The device provides schematic representations of the devices of the invention and are not to be considered accurate or limiting with regard to device element scale.

FIG. 1 depicts a top view of a semiconductor design 100 of dummy gate 8 on a nanosheet stack 10, in accordance with an embodiment of the present invention. As depicted, FIG. 1 includes dummy gates 8 over nanosheet stack 10. Also, illustrated in FIG. 1 is a location X-X of the cross-sections depicted in FIGS. 2-19. Also, illustrated in FIG. 1 is a distance, labeled CGP, where CGP is a contacted gate pitch. As known to one skilled in the art, CGP is the distance between the center of one gate and the center of an adjacent gate.

FIG. 2 depicts a cross-sectional view of semiconductor structure 200 after forming dummy gate 8 on nanosheet stack 10, in accordance with an embodiment of the present invention. As depicted, FIG. 2 includes hardmask (HM) 9 on each of dummy gate 8, nanosheet stack 10 composed of channel layers 7 and sacrificial layers 6 on bottom sacrificial layer 5, semiconductor (S/C) material 4, etch stop 3, and substrate 2.

Semiconductor substrate 2 may be, for example, a bulk substrate, which may be made from any of several known semiconductor materials such as, for example, silicon, germanium, silicon-germanium alloy, and compound (e.g., III-V and II-VI) semiconductor materials. Non-limiting examples of compound semiconductor materials include gallium arsenide, indium arsenide, indium phosphide, or indium gallium arsenide. Typically, semiconductor substrate 2 may be approximately but is not limited to, several hundred microns thick. In various embodiments, semiconductor substrate 2 is a wafer or a portion of a wafer. In some embodiments, semiconductor substrate 2 is composed of a semiconductor material that includes one or more of doped, undoped, or contains doped regions, undoped regions, stressed regions, or defect-rich regions. In some examples, semiconductor substrate 2 may include one or more other devices or transistors (not depicted). In an embodiment, semiconductor substrate 2 is one of a layered semiconductor substrate, such as a semiconductor-on-insulator substrate (SOI), germanium-on-insulator (GeOI), or silicon-on-replacement insulator (SRI).

Etch stop 3 is directly on substrate 2. Etch stop 3 may be composed of a semiconductor material, such as SiGe but is not limited to this material. In some embodiments, etch stop 3 is composed of a SiGe alloy composed of 20 to 40 atomic percent germanium (e.g., Si_{0.65}Ge_{0.35}). In other embodiments, etch stop 3 is a SiGe alloy with a different composition, another semiconductor material, or another semiconductor alloy.

S/C material 4 can be any semiconductor material. In various embodiments, S/C material 4 is a silicon material. S/C material 4 may be a portion of a silicon-on-insulator (SOI) substrate in some embodiments.

Nanosheet stack 10 is depicted on semiconductor (S/C) material 4. Nanosheet stack 10, as depicted in semiconductor structure 200 of FIG. 2, is composed of sacrificial layers 6, and channel layers 7 on bottom sacrificial layer 5. Each nanosheet layer of nanosheet stack 10 can be formed with known epitaxial growth processes. Each of bottom sacrificial layer 5, sacrificial layers 6, and channel layers 7, may be grown by epitaxy and can have a composition with an etch rate sensitivity that is different from semiconductor substrate 2 and S/C material 4. Additionally, bottom sacrificial layer 5, sacrificial layers 6, and channel layers 7 may each have compositions with a different etch rate sensitivity. As known to one skilled in the art, any number of nanosheet layers of sacrificial layers 6, channel layers 7, and/or bottom sacrificial layer 5 may form nanosheet stack 10.

Bottom sacrificial layer 5 can be a semiconductor material. In various embodiments, bottom sacrificial layer 5 is composed of SiGe. For example, bottom sacrificial layer 5 can be composed of Si_{0.45}Ge_{0.55} but may have another SiGe composition (e.g., with a germanium atomic concentration ranging from 40 to 65 percent) or may be composed of another semiconductor material(s).

Sacrificial layers 6 are composed of a semiconductor material that can be deposited or grown using one of a known epitaxy processes. In various embodiments, sacrificial layers 6 are composed of SiGe. For example, sacrificial layers 6 may have a germanium concentration ranging from about 20 atomic percent to about 40 atomic percent but is not limited to these materials and percentages. The sacrificial layers 6 have a different etch sensitivity than bottom sacrificial layer 5 and channel layers 7. Sacrificial layers 6 also have a different etch sensitivity than the material of semiconductor substrate 2 or S/C material 4.

Channel layers 7 are composed of a semiconductor material. As previously discussed, channel layers 7 may be grown or deposited by epitaxy using one of a known deposition process such as UHVCVD, RTCVD, LEPVD, MBE, or another similar semiconductor material growth process. In various embodiments, channel layers 7 are composed of a silicon material. In other embodiments, channel layers 7 are composed of any type IV semiconductor material or a compound (e.g., III-V or II-VI) semiconductor material. In various embodiments, channel layers 7 are intrinsic or undoped. In some cases, using known doping methods, channel layers 7 may be doped.

As depicted in FIG. 2, dummy gates 8 are formed using known semiconductor processes on the top channel layers 7 of nanosheet stack 10. Any known dummy gate material (e.g., polysilicon) can be used to form each of dummy gates 8 that are covered with a hardmask material such as HM 9.

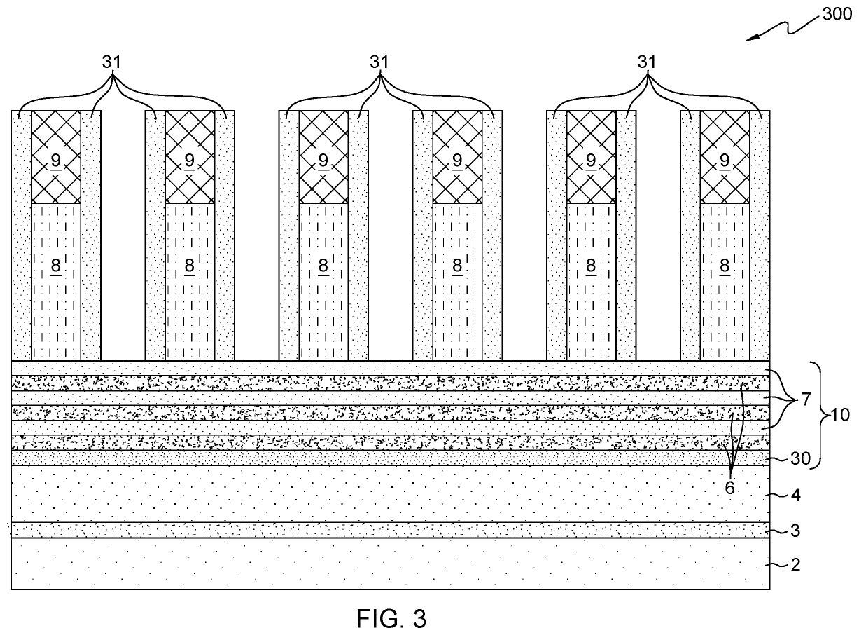

FIG. 3 depicts a cross-sectional view of semiconductor structure 300 after removing bottom sacrificial layer 5 and forming spacers 31 on dummy gates 8 and HM 9, in accordance with an embodiment of the present invention. As depicted, FIG. 3 includes spacers 31 on dummy gates 8 with HM 9, alternating layers of channel layers 7 and sacrificial layers 6 on bottom dielectric isolation (BDI) 30 of nanosheet stack 10, S/C material 4 contacting BDI 30 and etch stop 3 where etch stop 3 is on substrate 2.

Bottom sacrificial layer 5 can be selectively removed, for example, using a wet or dry lateral etching process such as a vapor phase HCl dry etch. A conformal deposition process such as ALD can deposit a dielectric material in the recesses left by the removal of bottom sacrificial layer 5 and on exposed surfaces of semiconductor structure 300. The dielectric material forming a bottom dielectric isolation layer (BDI) for BDI 30 on S/C material 4. BDI 30 is directly on S/C material 4 and under a bottom layer of sacrificial layers 6. BDI 30 may be composed of any suitable dielectric material such as but not limited to silicon nitride (SiN), silicon boron carbon nitride (SiBCN), silicon oxide carbon nitride (SiOCN), aluminum oxide (AlOx), and may include a single layer or may include multiple layers of dielectric material. BDI 30 may have a thickness ranging from about 3 nm to about 15 nm.

Using spacer formation processes, spacers 31 are formed. For example, a directional etch process such as RIE removes exposed horizontal portions of the dielectric material deposited on channel layers 7 and HM 9. In some embodiments, the spacer dielectric material is deposited in a different deposition process and with a different material than the deposition and material of BDI 30.

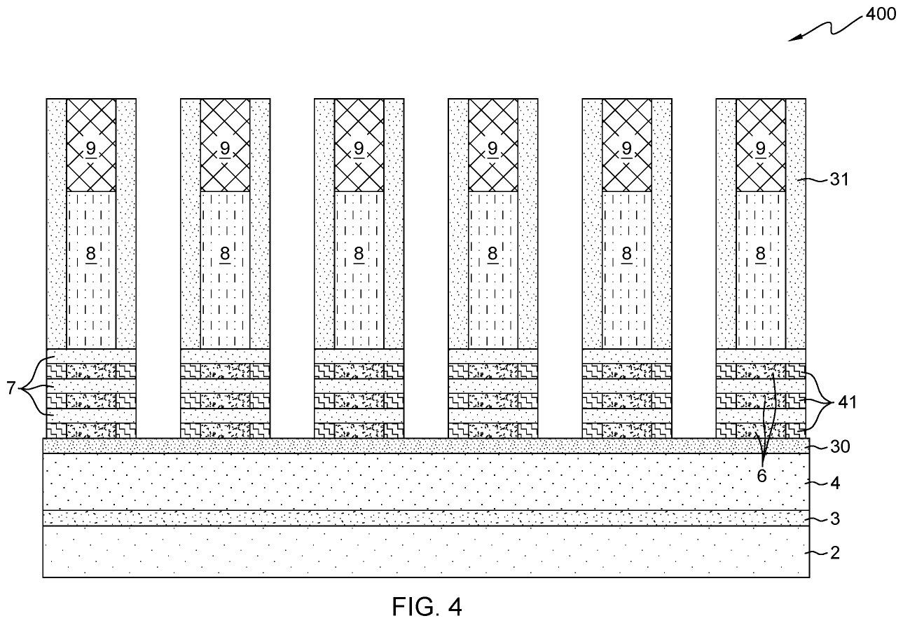

FIG. 4 depicts a cross-sectional view of semiconductor structure 400 after removing portions of sacrificial layers 6 and forming inner spacers 41, in accordance with an embodiment of the present invention. As depicted, FIG. 4 includes the elements of FIG. 3 without the outer edges of sacrificial layers 6 and with inner spacers 41.

In various embodiments, inner spacers 41 are formed by recessing the outer edges of sacrificial layers 6 (e.g., using one or more known lateral etching processes) followed by a conformal deposition of a dielectric material such as silicon oxide, silicon oxynitride, silicon nitride, SiBCN, SiOC, low-k dielectric or any combination of these materials for inner spacers 41. A directional etching process, such as RIE, removes the exposed outer horizontal portions of the dielectric spacer material to form inner spacers 41.

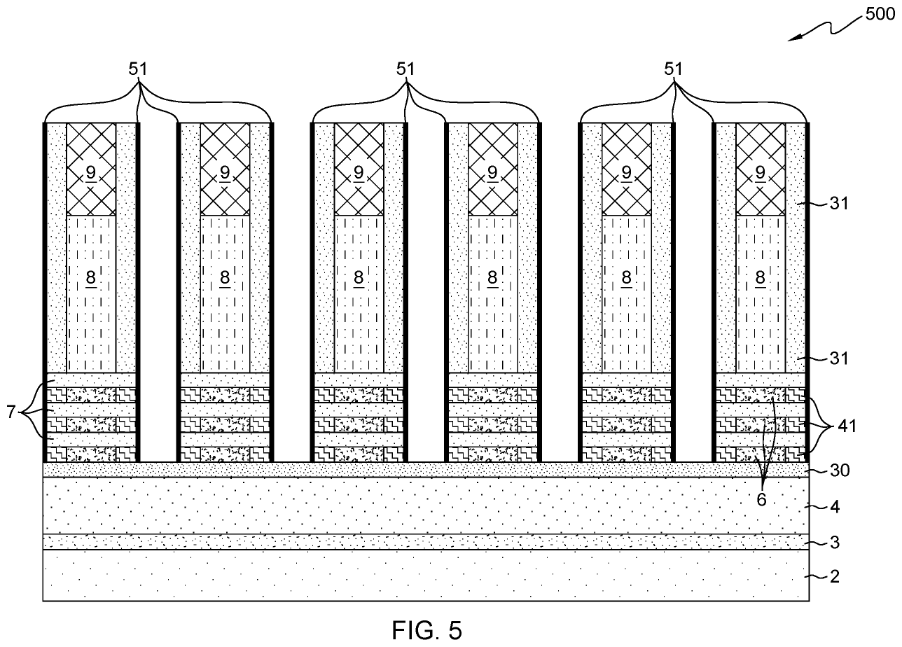

FIG. 5 depicts a cross-sectional view of semiconductor structure 500 after forming liners 51 around the sidewalls of the dummy gate 8 and the exposed sidewalls of channel layers 7 and inner spacer 41, in accordance with an embodiment of the present invention. A layer of a dielectric liner material, such as, but not limited to, SiN, SiBCN, SiOCN, AlOx, TiOx, AlNx, HfO2, SiCO, or SiC is deposited on semiconductor structure 500, for example, using ALD to form liners 51. A directional etch removes horizontal portions of the dielectric liner material leaving liners 51 on the sidewalls of inner spacers 41, channel layers 7, and spacer 31.

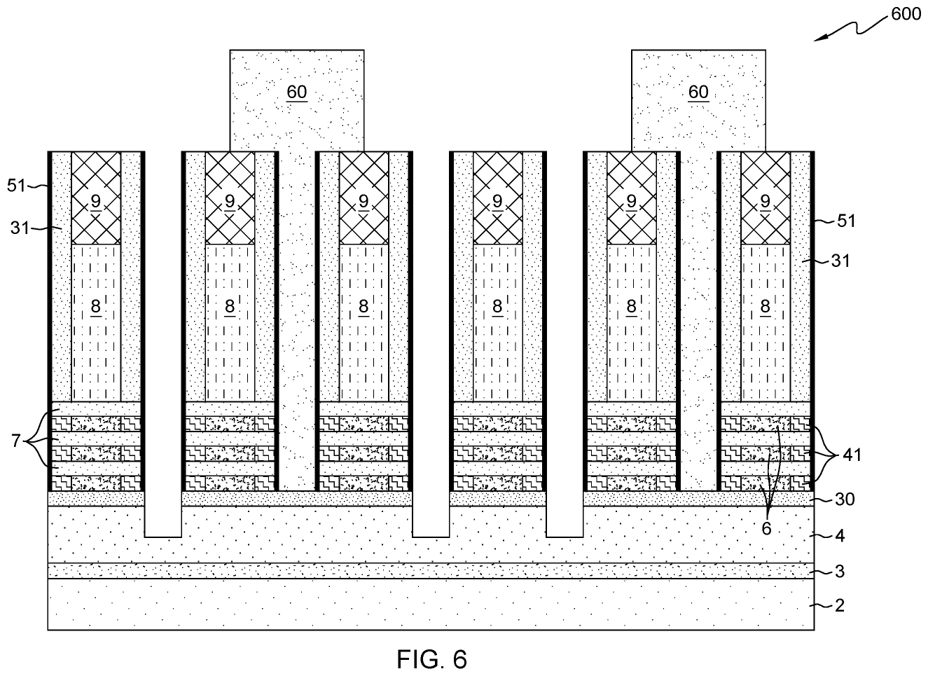

FIG. 6 depicts a top view of semiconductor structure 600 after depositing and patterning OPL 60 and removing exposed portions of BDI 30 and a top portion of S/C material 4, in accordance with an embodiment of the present invention. As depicted, FIG. 6 includes the elements of FIG. 5 with OPL 60 patterned over some HM 9, liners 51, and spacers 31 and the exposed portions of BDI 30 and a top portion of S/C material 4 removed under the exposed portions of the removed BDI 30. The layer of OPL 60 is deposited over exposed surfaces of at least three or more nanosheet stacks (i.e., over liners 51, spacers 31, HM 9) and BDI 30. The three or more nanosheet stacks are composed of dummy gates 8 covered by HM 9 and spacers 31, channel layers 7, inner spacers 41 surrounding sacrificial layers 6. The removed portions of BDI 30 and S/C material 4 create an opening for later backside contact formation.

As depicted in FIG. 6, the top surface of two leftmost portions of HM 9 surrounded by liners 51 and spacers 31 are not covered by OPL 60 leaving the portion of BDI 30 between the two stacks of channel layers 7 and inner spacers 41 surrounded by liners 51. As depicted in FIG. 6, the etching process removes one exposed portion of BDI 30 and S/C material 4 on the left portion of FIG. 6. Additionally, as depicted in FIG. 6, the etching process removes two top portions of BDI 30 and S/C material 4 on the right side of FIG. 6. The two top portions of S/C material 4 under the two exposed portions of BDI 30 are adjacent to a bottom of a center stack of liners 51, inner spacers 41, sacrificial layers 6, and channel layers 7. Specifically, BDI 30 and the top portion of S/C material 4 are removed directly adjacent to the bottom of the third from the right stack of liners 51, inner spacers 41, sacrificial layers 6, and channel layers 7 under dummy gate 8, HM 9, and spacer 31. Etching portions of BDI 30 and a top portion of S/C material 4 exposes a lower or middle portion of S/C material 4.

While FIG. 6 depicts one portion of BDI 30 and S/C material 4 removed between the base of the two leftmost stacks of liners 51, inner spacers 41, sacrificial layers 6, and channel layers 7 and two portions of BDI 30 and substrate 2 removed around the base of another central stack of liners 51, inner spacers 41, sacrificial layers 6, and channel layers 7. In other examples (not depicted in FIG. 6) any number of portions of BDI 30 and substrate 2 may be removed directly adjacent to the bottom of liners 51. For example, in another example, OPL 60 is not deposited on and between liners 51, spacers 31, the two rightmost HM 9, and the portion of BDI 30. In this example, three portions of BDI 30 and substrate 2 directly adjacent to five of liners 51 around three adjacent stacks of inner spacer 41, sacrificial layers 6, and channel layers 7 are removed. In this example, after performing the processes discussed later with respect to FIGS. 2-19, each of three source/drains contact the top surfaces of the backside contact (not depicted) and are merged into the bottom surface of the single backside contact connecting with a backside power rail. In other words, each three top surface contacts of the backside contact each connected to one of the three source/drains and are merged into a single bottom surface of the backside contact connecting to the backside power rail.

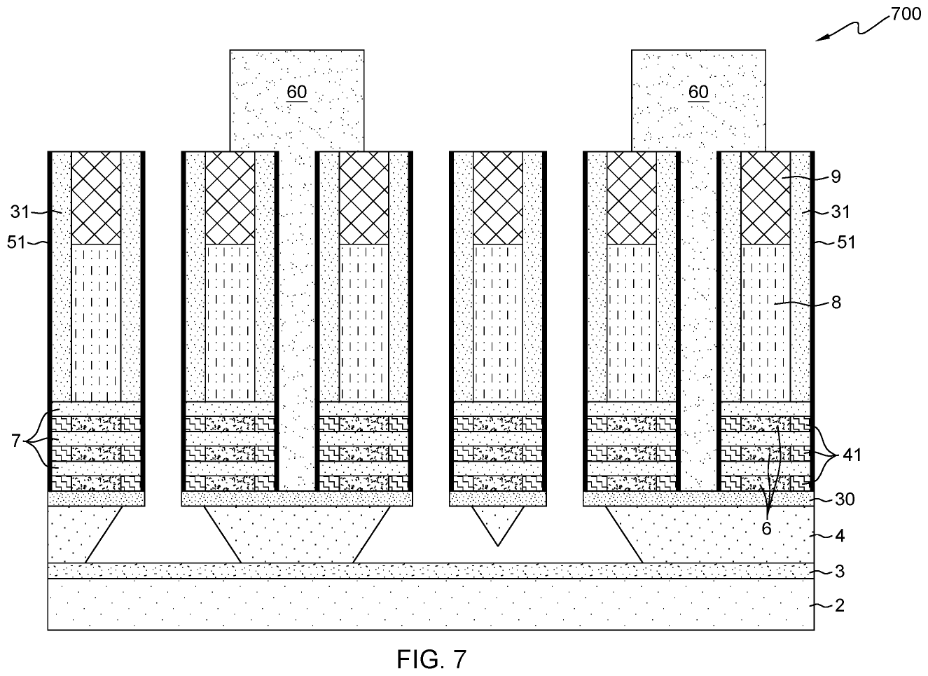

FIG. 7 depicts a cross-sectional view of semiconductor structure 700 after etching cavities extending out from the removed top portions of S/C material 4 below removed portions of BDI 30, in accordance with an embodiment of the present invention. As depicted, FIG. 7 includes the elements of FIG. 6 with more portions of S/C material 4 removed around previously removed top S/C material 4 (i.e., removed in FIG. 6). The etching process removes bell-like or cone-like cavity in S/C material 4 under BDI 30. The etching process removes increasingly wider portions of exposed surfaces of S/C material 4 down to etch stop 3.

As depicted in FIG. 7, the two connecting merging cavities in S/C material 4 are removed on the center-right portion of semiconductor structure 700 along with a third cone-shaped cavity in S/C material 4 near the left side of semiconductor structure 700. In various embodiments, an anisotropic etch process forms the cavities depicted in FIG. 7. The sigma-shape forming silicon etch process is a known semiconductor process. For example, using an anisotropic dry silicon etch using HBr, Cl₂, He that stops on etch stop 3 can form the cavities depicted in FIG. 7.

The cavities in S/C material 4 extend down under the bottom surface of BDI 30 to a top surface of etch stop 3. As depicted in FIG. 7, the leftmost cavity has a trapezoidal-shape in the cross-sectional view of FIG. 7. The two rightmost cavities depicted in FIG. 7 each have a trapezoidal shape in the cross-sectional view and overlap or merge. In this case, the cross-section of the two rightmost overlapping cavities can form an M. The shape of the two merged cavities in three-dimensions (not just a cross-sectional view) can look like two adjacent connected mountains. The leftmost cavity is not merged with another cavity and would have a three-dimensional shape of a single mountain (e.g., with a wider bottom).

The etching process creates a cone-like opening above etch stop 3. In some embodiments, a sigma-shape silicon etch using the anisotropic dry silicon etch creates the cone like cavity shape depicted in FIG. 7 that stops on etch stop 3. The cavities, as depicted in FIG. 7, have a wider bottom surface contacting etch stop 3 and a narrower top opening. A portion of the cavities contact the bottom surface of BDI 30. As depicted in the right side of FIG. 7, the cavity formed below the two removed portions of BDI 30 has outer edges in the center that overlap forming a large M-shaped cavity in the cross-sectional view provided by FIG. 7 where the two removed portions of BDI 30 create the upper points or portions of the M in the cross-section depicted in FIG. 7. The two cavities can be overlapping or joined cavities that form larger backside contacts depicted later after later backside contact formation processes. As previously discussed, creating larger backside contact with the large cavities depicted in FIG. 7 can result in later backside contact formation where the backside contacts formed in the cone-like cavities can have a larger bottom surface.

In other embodiments, more cavities or openings than the openings depicted in FIG. 7 are formed. For example, more than two connected cavities under more than two adjacent removed portions of BDI 30. In this case, more than two connecting cavities can have overlapping outer edges forming three or more connected cavities (e.g., a cavity formed with two M-shaped openings in cross-section that can have two or three upside-down cone-like wedges of S/C material 4 remaining between the adjacent cavities). For example, two upside-down cone-like wedges of S/C material 4 form when rightmost portion of a first M-shaped cavity is aligned with the leftmost portion of a second M-shaped cavity resulting in three mountain-shaped portions of the cavity under three S/D 95 with two wedge-shaped portions of S/D material 4 between the three mountain-shaped cavities.

As depicted in FIG. 7, both (1) the left side single cavity between two sides of one of liners 51 covering the outer edges of two stacks of inner spacers 41 and channel layers 7 and (2) the two merged cavities in the right portion of semiconductor structure 700 both create a larger open area than a typical backside contact hole. A conventional backside contact hole is typically a cylindrical shaped hole with nearly vertical sidewalls while the cavities formed in FIG. 7 create a flattened cone-like opening on the left side of FIG. 7 and M-shaped or a cavity that looks like two mountains on the right side of FIG. 7.

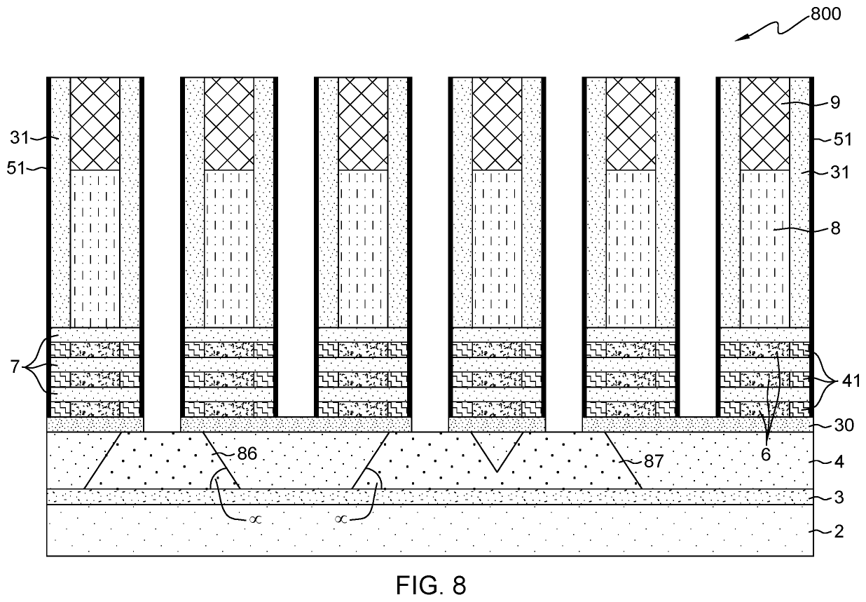

FIG. 8 depicts a cross-sectional view of the semiconductor structure after removing OPL 60 and growing placeholder 86 and placeholder 87 in the cavities, in accordance with an embodiment of the present invention. As depicted, FIG. 8 includes the elements of FIG. 7 with placeholder 86 and placeholder 87 grown by epitaxy on etch stop 3. Also, identified in FIG. 8 are angles o of the sidewalls of placeholder 86 and 87 with etch stop 3. As depicted in FIG. 8, angle σ is less than 90 degrees. For example, angle σ of the sidewalls of placeholder 87 and placeholder 87 may be 40 to 80 degrees but is not limited to this range.

As depicted in FIG. 8, placeholder 86 fills the cavity in substrate 2 on the left side of semiconductor structure 800 and placeholder 87 fills the two merged cavities in the right-center portion of semiconductor structure 800. Placeholders 86 and 87 can be composed of any semiconductor material capable of being grown on etch stop 3 that has a different etch selectivity than substrate 2 and etch stop 3 materials. For example, placeholder 86 and 87 can be composed of SiGe. In various embodiments, etch selectivity of placeholder 86 and 87 material is different than etch stop 3 or substrate 2. For example, placeholders 86 and 87 have a different concentration or amount of germanium than etch stop 3 material.

As depicted in FIG. 8, the epitaxial growth of placeholder 86 and 87 in the cavities results in a sloped sidewall of each cavity where the angle σ of the sidewalls of placeholder 86 and 87 with the top surface of etch stop 3 is less than 90 degrees

The flattened cone shaped cavities formed as discussed with reference to FIG. 7 fill with the epitaxy semiconductor material of placeholder 86 and 87 material forming a flattened cone shaped portion of placeholder 86 on the left side of semiconductor structure 800 and an M-shaped portion of placeholder 87 near the center portion of semiconductor structure 800. Both epitaxially grown portions of placeholders 86 and 87 have a wider bottom surface than the top surface of placeholders 86 and 87. After epitaxy, the central portion of placeholder 87, filling the two merged cavities of FIG. 6, has a bottom surface width that is almost twice as large as the leftmost placeholder 86.

As depicted, placeholder 86 is between and below two adjacent nanosheet stacks. After the semiconductor processes depicted in FIGS. 1-8, the two adjacent nanosheet stacks can be composed inner spacers 41 and liners 51 around sacrificial layers 6 on BDI 30, channel layers 7, and dummy gates 8. Dummy gates 8 include inner spacers 41 and spacers 31. The area of the top surface of placeholder 86 is approximately 20-60% less than the contact area of the bottom of placeholder 86 with etch stop 3.

Similarly, placeholder 87 has two top surfaces between three nanosheet stacks separated by the upside cone-like wedge of S/C material 4 where the two top surfaces of placeholder 87 have a surface area that is approximately 60-120% larger than the combined area of the two top surfaces.

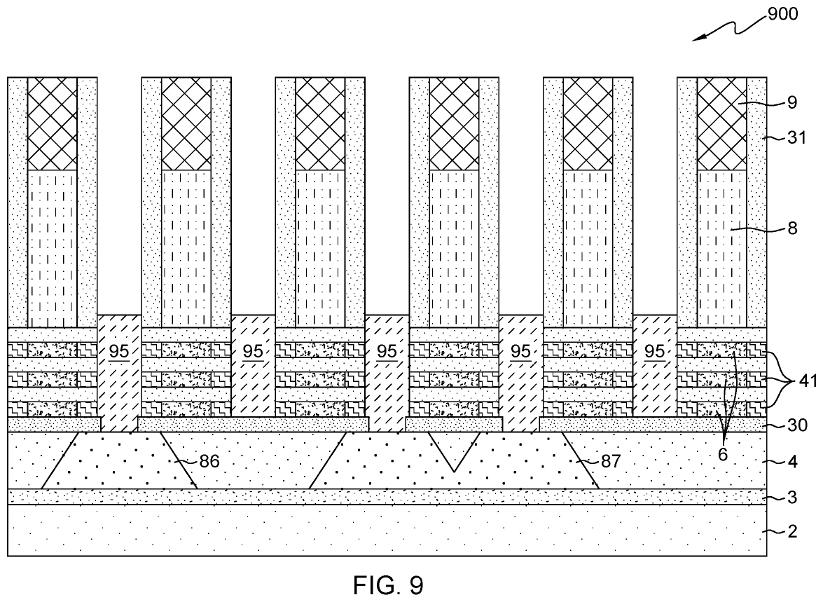

FIG. 9 depicts a cross-sectional view of semiconductor structure 900 after removing liners 51 and growing the source/drain (S/D) 95, in accordance with an embodiment of the present invention. As depicted, FIG. 9 includes the elements of FIG. 8 without liners 51 and with S/D 95. As depicted, FIG. 9 includes S/D 95, substrate 2, etch stop 3, placeholder 86 and 87. S/C material 4, BDI 30, inner spacers 41, sacrificial layers 7, channel layers 7, spacers 31, dummy gates 8, and HM 9.

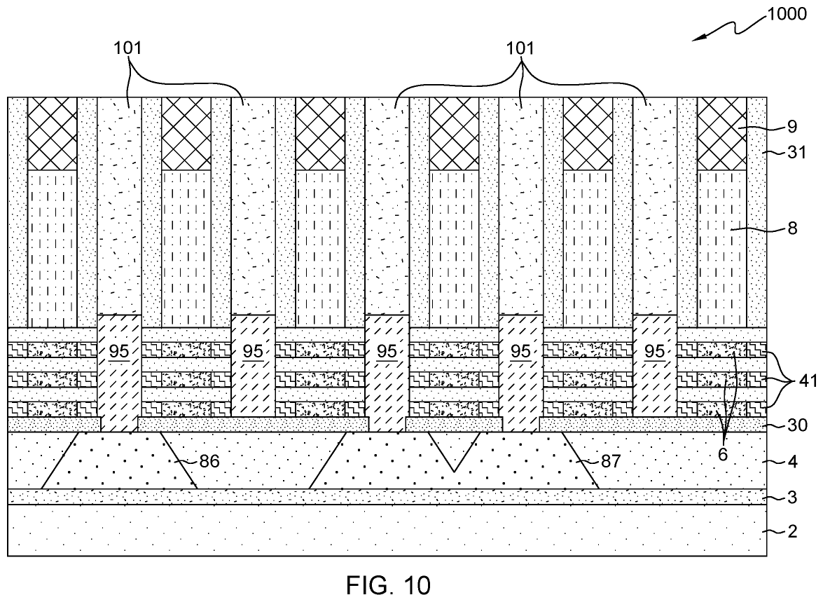

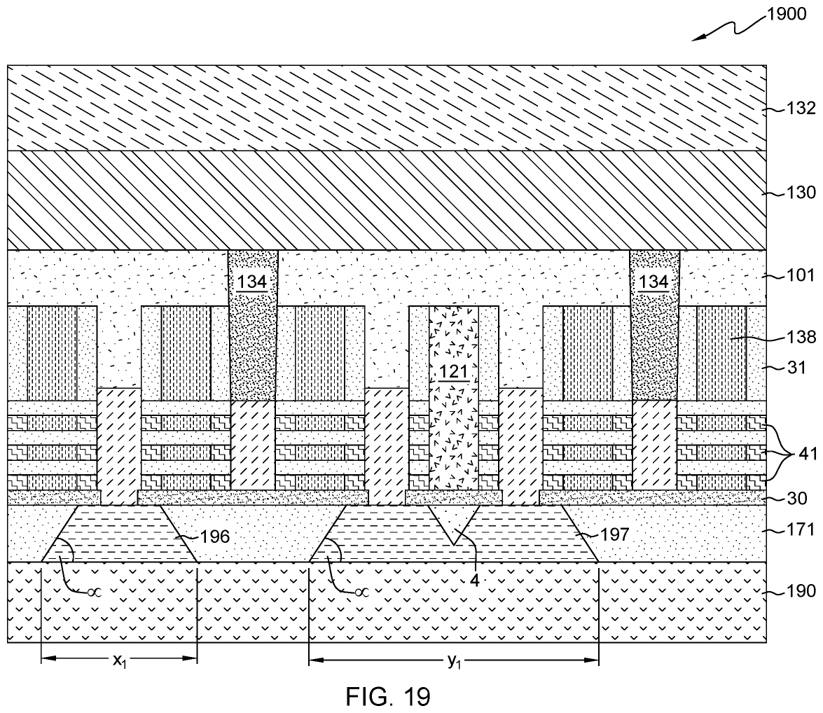

Using epitaxy, S/D 95 grows on exposed surfaces of BDI 30 and placeholder 86 and 87. As depicted, the top surface of S/D 95 is above the top of the top layer of channel layers 7 and extends a little over the bottom portion of sidewall spacers 31. In some embodiments, S/D 95 is doped. For example, bottom S/D 95 is doped by adding one or more dopant species, such as boron, phosphorous, or another semiconductor doping material, to the epitaxial source/drain material of S/D 95. S/D 95 may be composed of any known source/drain material. Each of the two adjacent S/D 95 grown on placeholder 187 and the S/D 95 grown on placeholder 186 are longer than the other S/D 95 grown on BDI 30 (i.e., the S/D 96 not grown on placeholder 186 and 187). In this way, the two adjacent S/D 95 grown in contact with inner spacers 41, channel layers 7, and spacer 31 on placeholder 186 and placeholder 187 extend below the top surface of BDI 30 to contact placeholder 186 and 187. The two adjacent S/D 95 have a bottom surface that is level with a bottom surface of BDI 30. The two adjacent S/D 95 with a bottom surface that is level with the bottom surface of BDI 30 have an extended length and are larger than S/D 95. As depicted later in FIG. 19, the two adjacent S/D 95 contacting inner spacers 41, channel layers 7, spacers 31 that surround and contact a single diffusion break (SDB 121) will contact backside contacts 196 and backside contact 197. Backside contact 196 and backside contact 197 will replace placeholder 86 and placeholder 87, respectively after the processing steps depicted in FIGS. 10-19.

FIG. 10 depicts a cross-sectional view of semiconductor structure 1000 after depositing ILD 101 and performing a CMP, in accordance with an embodiment of the present invention. As depicted, FIG. 10 includes the elements of FIG. 9 and ILD 101.

Using known deposition processes, such as CVD or PVD, a dielectric material for ILD 101 is deposited over semiconductor structure 900. A CMP can be performed to form semiconductor structure 1000.

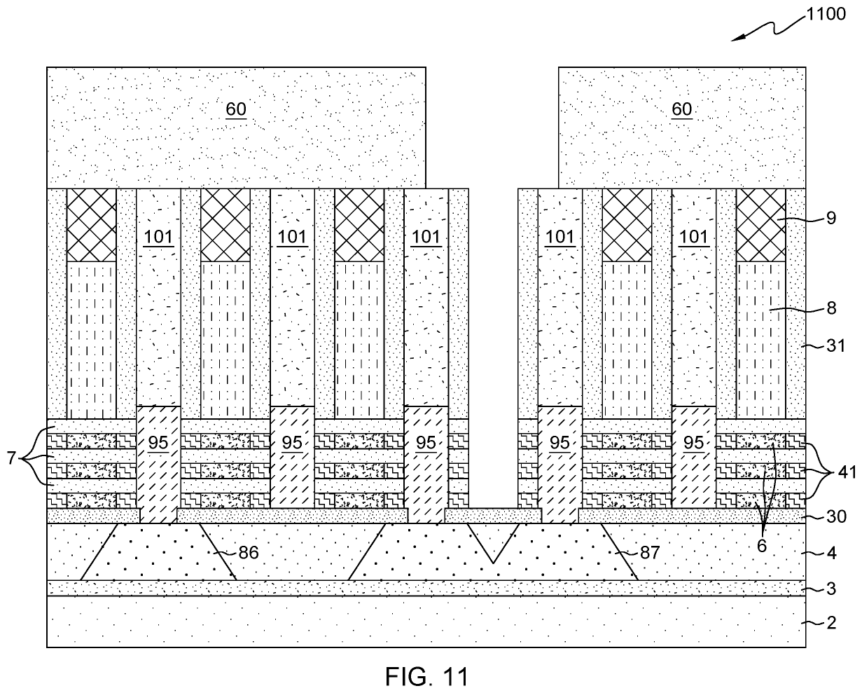

FIG. 11 depicts a cross-sectional view of semiconductor structure 1100 after depositing and patterning another layer of OPL 60 and removing the exposed portion of HM 9 and dummy gate 8, channel layers 7, and sacrificial layers 6 under the removed portion of HM 9, in accordance with an embodiment of the present invention. As depicted, FIG. 11 includes the elements of FIG. 10 with patterned OPL 60 and without a S/D 95 under a central removed dummy gate 8 and HM 9 that were not covered by OPL 60. The removal of the central dummy gate 8 is optional in an embodiment.

Removing HM 9 and dummy gate 8, channel layers 7, and sacrificial layers 6 under the removed portion of HM 9 exposes a portion of BDI 30 above the wedge-shaped portion of S/C material 4. The wedge-shaped portion of S/C material 4, as depicted, is surrounded by placeholder 87. HM 9, dummy gate 8, channel layers 7, and sacrificial layers 6 may be removed by a known etching process (e.g., RIE or a wet etch).

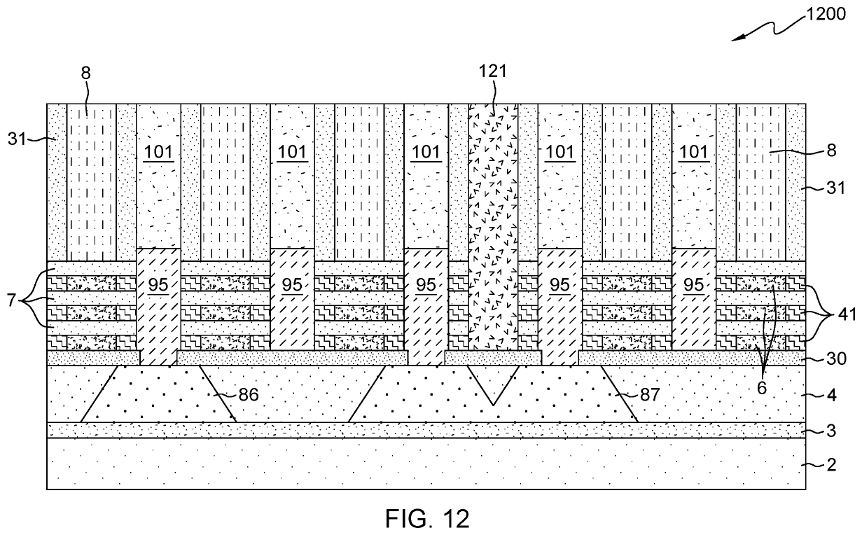

FIG. 12 depicts a cross-sectional view of semiconductor structure 1200 after depositing single diffusion break (SDB) 121 and performing a CMP, in accordance with an embodiment of the present invention. As depicted, FIG. 12 includes the elements of FIG. 11 and SDB 121. As known to one skilled in the art, a single diffusion break may reduce the cell-to-cell spacing by reducing the width of the shallow trench isolation to a single dummy poly gate length. The deposition of SDB 121 is optional. In an embodiment, the central dummy gate 8 is not removed in FIG. 11 and in this case, SDB 121 is not deposited and dummy gate 8 is not removed.

SDB 121 is composed of a dielectric material, such as but not limited to SiO₂. SiN, SiCO, SiBCN, or Al₂O₃. In some embodiments, a fill material such as but not limited to amorphous silicon is deposited over a layer of dielectric material to form SDB 121 after CMP. Using known deposition processes, such as CVD, ALD, or PVD, a layer or layers of materials for SDB 121 are deposited over the semiconductor structure of FIG. 11 to form semiconductor structure 1200 after performing a CMP. As depicted in FIG. 12, SDB 121 is over a portion of BDI 30 above the wedge of S/C material 4 between the peaks or between the two flattened top surfaces of placeholder 87.

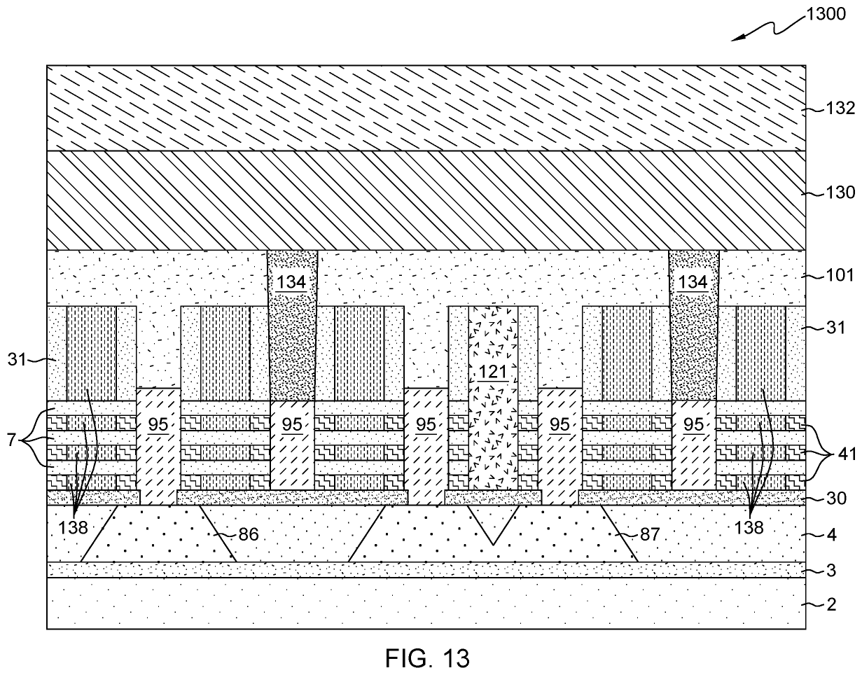

FIG. 13 depicts a cross-sectional view of semiconductor structure 1300 after formation of gate 138, which can be a replacement metal gate, ILD 101 deposition, contact 134 formation, BEOL interconnect wiring 130 formation, and carrier wafer 132 bonding, in accordance with an embodiment of the present invention. As depicted, FIG. 13 includes the elements of FIG. 12 with an additional layer of ILD 101 on the top surface of semiconductor structure 1200, two contacts 134, BEOL interconnect wiring 130, and carrier wafer 132 bonded to BEOL interconnect wiring 130. Using known semiconductor processes, semiconductor structure 1300 can be formed. For example, dummy gates 8 can be replaced with gate 138 with known replacement metal gate processes. In various embodiments, gate 138 is a replacement metal gate.

Using known lithographic and etching processes, the additional layer of ILD 101 is patterned and etched. Using known contact formation processes, the two contacts 134 are formed on the exposed S/D 95, where the exposed S/D 95 under contacts 134 are each S/D 95 that reside on a portion of BDI 30. In various embodiments, contacts 134 are middle-of-line (MOL) contacts. The two exposed S/D 95 are on BDI 30 (i.e., the two S/D 95 under contacts 194 do not contact either of placer holder 186 or 187). In various embodiments, contacts 134 may be composed of a contact material, such as tungsten, cobalt, copper, tantalum, molybdenum, ruthenium, a metal compound, such as, titanium nitride, tantalum nitride, tungsten nitride, or a combinations of these materials. BEOL processes form BEOL interconnect wiring 130 directly above ILD 101 and contacts 134. Each of contacts 134 connect one S/D 95 on BDI 30 to BEOL interconnect wiring 130, as depicted in FIG. 13. Using known carrier wafer bonding processes, carrier wafer 132 is attached to BEOL interconnect wiring 130.

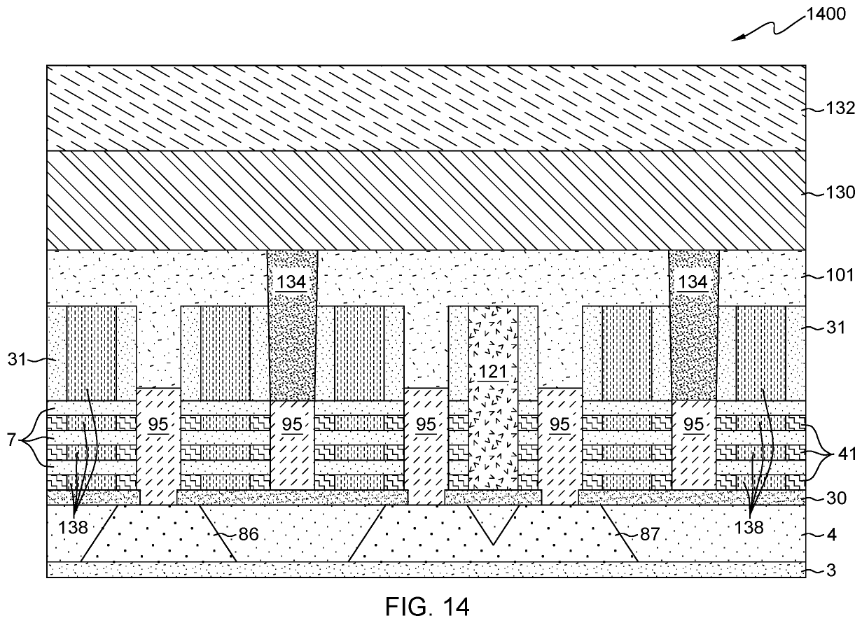

FIG. 14 depicts a cross-sectional view of semiconductor structure after wafer flip and substrate 2 removal, in accordance with an embodiment of the present invention. As depicted, FIG. 14 includes the elements of FIG. 13 with substrate 2 removed. For example, substrate 2 may be remove by one or more of a wafer grind process or an etching process. In various embodiments, semiconductor structure 1300 of FIG. 13 is flipped. The flipped semiconductor structure 1300 with carrier wafer 132 under BEOL interconnect wiring 130 is not depicted in FIG. 14 for consistency with previous FIGs. Semiconductor structure 1400 is not depicted as a flipped wafer. Similarly, semiconductor structures 1500, 1600, 1700, 1800, and 1900 are not depicted as flipped while, in actuality, for processing these semiconductor structures can be flipped. Using known wafer grinding and etching processes, substrate 2 is removed exposing the surface of etch stop 3.

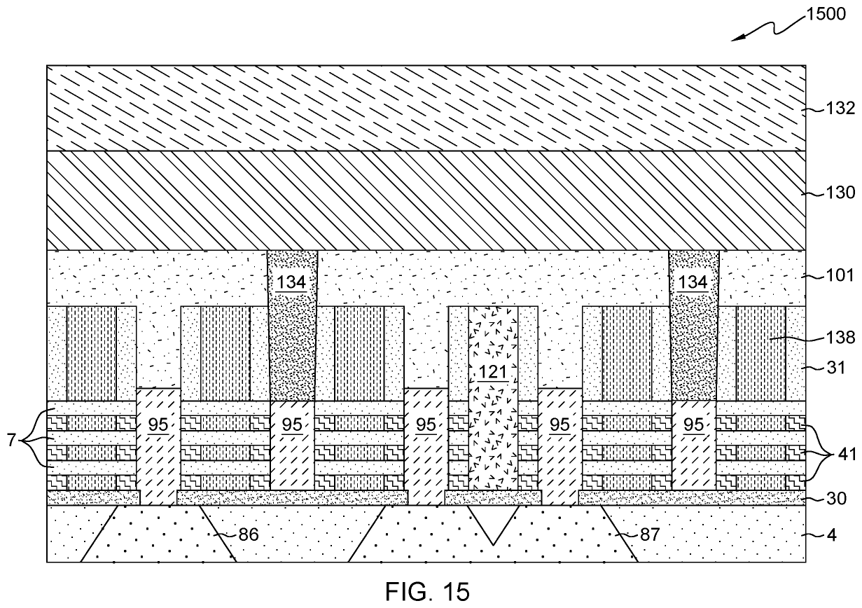

FIG. 15 depicts a cross-sectional view of semiconductor structure 1500 after etch stop 3 removal, in accordance with an embodiment of the present invention. As depicted, FIG. 15 includes the elements of FIG. 14 minus etch stop 3. After removing etch stop 3 using one or more known etching processes, the surfaces of S/C material 4, placeholders 86 and 87 are exposed.

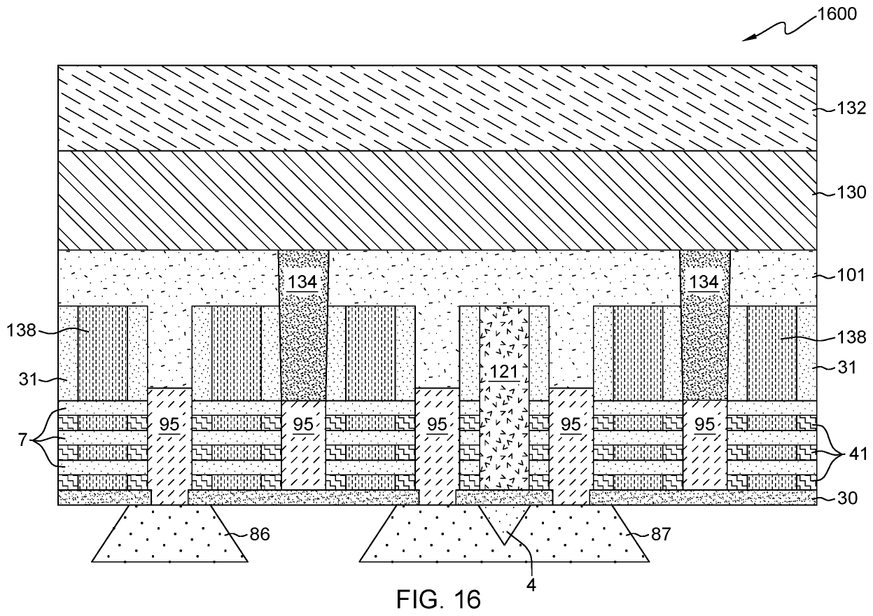

FIG. 16 depicts a cross-sectional view of semiconductor structure 1600 after removing exposed portions of S/C material 4, in accordance with an embodiment of the present invention. As depicted, FIG. 16 includes the elements of FIG. 15 without S/C material 4 that is outside of placeholder 86 and 87. After removing the exposed portions of S/C material 4, the wedge-shaped portion of S/C material 4 encased between the two cone-like portions of placeholder 87 remains.

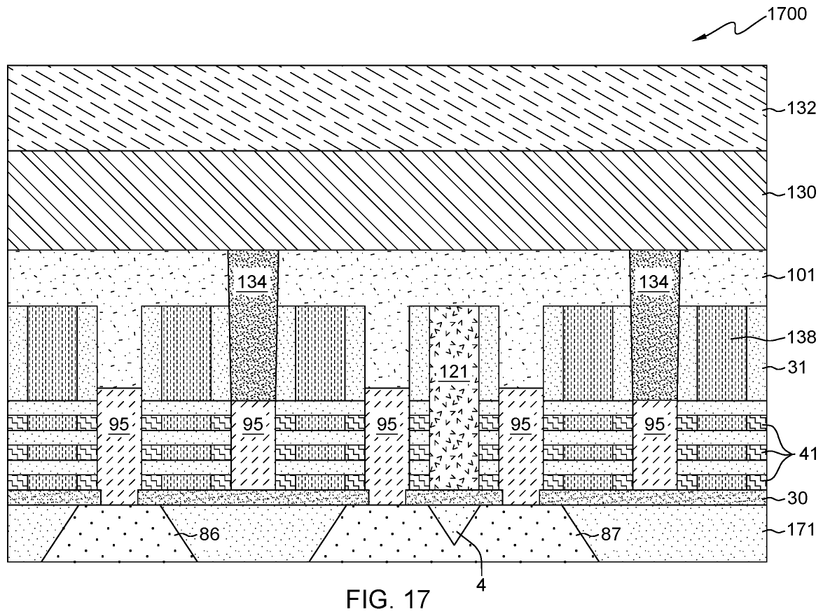

FIG. 17 depicts a cross-sectional view of semiconductor structure 1700 after depositing backside ILD 171, in accordance with an embodiment of the present invention. As depicted, FIG. 17 includes the elements of FIG. 16 and backside ILD 171. Using a deposition process (e.g., CVD, ALD, etc.), a layer of ILD 171 is deposited on exposed surfaces of BDI 30 and around placeholder 86 and 87. A CMP planarizes semiconductor structure 1700.

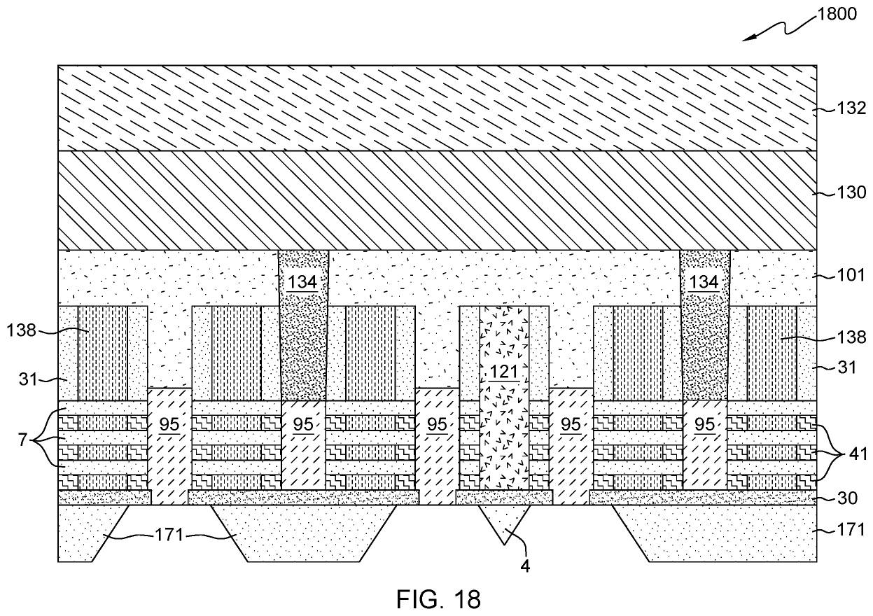

FIG. 18 depicts a cross-sectional view of semiconductor structure 1800 after removing placeholder 86 and 87, in accordance with an embodiment of the present invention. As depicted, FIG. 18 includes the elements of FIG. 17 without placeholder 86 and 87. Using one or more known semiconductor material etching processes, placeholders 86 and 87 are removed leaving cone shaped cavities in backside ILD 171 under the exposed S/D 95 and portions of BDI 30 adjacent to the exposed S/D 95.

FIG. 19 depicts a cross-sectional view of semiconductor structure 1900 after forming backside contacts 196 and 197, backside power rail (BSPR) 190, and backside power delivery network (BSPDN) 192, in accordance with an embodiment of the present invention. As depicted, FIG. 19 includes backside contacts 196 and 197 where backside contact 197, BSPDN 192. BSPR 190, S/C material 4 inside backside contact 197, BDI 30, S/D 95, a GAA nanosheet FET composed of inner spacers 41, spacers 31, gate 138, channel layers 7, contacts 134 connecting two of S/D 95 to BEOL interconnect wiring 130, SDB 121, ILD 101, and carrier wafer 132. Also, illustrated in FIG. 19 is the width x1 of the bottom surface of backside contact 196 contacting BSPR 190 and the width y1 of the bottom surface of backside contact 197 contacting BSPR 190. As depicted in FIG. 19, the width x1 and y1 is the width, which may also be considered a length of the bottom surface area of backside contacts 196 and 197, respectively, along a centerline between the two adjacent semiconductor devices connecting to the S/D 95 that contacts backside contact 196 or between the two adjacent S/D 95 connecting to backside contact 197.

Using known contact formation processes, backside contact 196 and backside contact 197 can be formed. For example, a deposition of a contact material, such as but not limited to, tungsten, cobalt, copper, tantalum, molybdenum, ruthenium, a metal compound, such as, titanium nitride, tantalum nitride, tungsten nitride, or a combinations of these materials over the exposed portions of BDI 30, backside ILD 171, and S/D 95 occurs by CVD or ALD. A CMP removes excess contact material over backside ILD 171. After CMP, backside contact 196 can be a flattened cone shaped contact with a narrower top surface on the leftmost S/D 95. Backside contact 196 has a wider bottom surface that is depicted in FIG. 19 below one of S/D 95. Backside contact 196 with a wider bottom surface contacting BSPR 190 can provide a lower resistance to improve semiconductor device electrical performance compared to a conventional backside contact.

Backside contact 196 is an enlarged contact with a much wider bottom surface than top surface. The top surface of backside contact 196 contacts one of S/D 95 of a GAA nanosheet FET device and a portion of BDI 30 around the S/D 95 contacting backside contact 196. The semiconductor device that is depicted as a t GAA nanosheet device is composed of a S/D 95, inner spacers 41, channel layers 7, and gate 138. S/D 9/5 contacts backside contact 196 through an opening in BDI 30. S/D 95 contacting backside contact 196 is longer than the S/D 95 that do not contact a backside contact in FIG. 19. As depicted, the slope of the sidewall of backside contact 196 and 197 is less than 90 degrees creating an angle σ with a magnitude less than 90 degrees and in the range of 40 to 80 degrees but is not limited to this range.

The area of the bottom surface of backside contact 196 is approximately 20-200% greater than the contact area of the top surface of backside contact 196. The larger contact area of backside contact 196 with BSPR 190 can reduce the electrical resistance and the thermal resistance of the connection to BSPR 190 to improve the electrical performance of the GAA nanosheet FETs connected through S/D 95 to backside contact 196.

As depicted in FIG. 19, width x1 is the width of the bottom surface of backside contact 196. The width x1 of bottom surface of backside contact 196 can be approximately 1 CGP where the width x1 is measured in a direction parallel to the centerline extending between the two adjacent semiconductor devices. In various embodiments, the width of the bottom surface of backside contact 196 (labeled as x1) is between 60 to 120 percent of a CGP distance (i.e., the distance between centers of the two adjacent gates 138 not connected to the two adjacent S/D 95 contacting backside contact 196). As depicted in FIG. 19, inner spacers 41 and a bottom portion of spacers 31 separate gate 138 from each of the two adjacent S/D 95 contacting a top surface of backside contact 196. The wider bottom surface of backside contact 196 enlarges backside contact 196 compared to a conventional backside contact. For example, angle σ of the sidewall of backside contact 196 may be 40 to 80 degrees but is not limited to this range. The smaller angle σ is the larger the bottom surface of backside contact 196 is. The enlarged bottom surface of backside contact 196 reduces the electrical resistance of the connection backside contact 196 with BSPR 190 and can improve the electrical performance of the semiconductor devices (e.g., GAA nanosheet FETs). Backside contact 196 with the enlarged bottom surface improves the electrical connection between the two adjacent S/D 95 and BSPR 190.

After CMP, backside contact 197 can be two joined or merged cone shaped contacts, where the two top surfaces of backside contact 197 merge into a single bottom surface of backside contact 197. The two top surfaces of backside contact 197, as depicted, are each under one of two adjacent S/D 95 on either side of SDB 121. The top portions of backside contact 197 can be two cone-like elements where each cone-like top portion of backside contact 197 contact one of S/D 95 and merge in a bottom or middle portion to form a single bottom surface of backside contact 197. Each of the two cones under an S/D 95 connect in the bottom or middle portion of each of the two cones to form backside contact 197 (e.g., the two joined cones appear as two flat-topped mountains with an M-shape in the cross-section depicted in FIG. 19).

As depicted in FIG. 19, backside contact 197 is between and partially below two adjacent semiconductor devices that are each a GAA nanosheet FET. Each of the two adjacent semiconductor devices contacting backside contact 197 are depicted as two adjacent GAA nanosheet FETs that are composed of inner spacers 41, channel layers 7, S/D 95, and gate 138 with spacers 31 where SDB 121 is between the two adjacent semiconductor devices and contacts inner spacers 41, channel layers 7, and spacer 31. SDB 121 is on a portion of BDI 30 between the two adjacent S/D 95 of the two adjacent GAA nanosheet FETs that connect to backside contact 197.

In FIG. 19, width y1 of the bottom surface of backside contact 197 that is contacting BSPR 190 is approximately the width of 2 CCP or two contacted gate pitches. As depicted in FIG. 19, the width y1 is measured approximately between the centers of the two gates 138 of the two GAA nanosheet devices composed of channel layers 7 contacting an adjacent S/D 95, gates 138 with inner spacers 41 and spacers 31. In some embodiments, width y1 of the bottom surface of backside contact 197 is between 60 to 120 percent of the width of two CGPs (e.g., the distance between the centers of three adjacent gates 138). While FIG. 19 depicts backside contact 197 under two GAA nanosheet FETs each composed of channel layers 7, gate 138 with inner spacers 41, spacers 31, and S/D 95, as known to one skilled in the art, backside contact 197 could be formed with other types of semiconductor devices (e.g., finFET, vertical FETs, phase-change memory devices). The two top portions of backside contact 197 each contact one of the two adjacent S/D 95 and a portion of BDI 30 adjacent to the two adjacent S/D 95 contacting backside contact 197. The combined area of the two top surfaces of backside contact 197 is smaller than the bottom surface of backside contact 197 contacting BSPR 190. The width of the contact area of the bottom surface of backside contact 197, illustrated as width y1, between the two adjacent semiconductor devices may be approximately 70 to 500% greater than the combined contact area of the two top surfaces of backside contact 197 but is not limited to this range. The larger contact area of backside contact 197 with BSPR 190 can reduce the electrical resistance and the thermal resistance of the connection to BSPR 190 to improve the electrical performance of the GAA nanosheet FETs connected through the two adjacent S/D 95 to backside contact 197.

The slope of the sidewalls of backside contact 197 with BSPR 190, illustrated as angle σ in FIG. 19, is less than 90 degrees and may be in the range of 40 to 80 degrees but is not limited to these angles. In cross-section, backside contact 197 has a profile or outline that looks like an M with a middle V-like portion of S/C material 4 creating center dip of the M. The portion of S/C material 4 is directly under BDI 30 below SDB 121. The upside-down cone shaped wedge of S/C material 4 is directly contacting BDI 30 and under SDB 121. The upside-down cone shaped wedge of S/C material 4 is depicted between and below the two S/D 95 (e.g., below and between the two GAA nanosheet FET devices abutting SDB 121).

The two top surfaces of backside contact 197 connect to two adjacent S/D 95 and the backside contact 197 connects into one surface of BSPR 190. In this way, each top surface of backside contact 197 receives the current from one semiconductor device (e.g., received one device current from a S/D 95 of a GAA nanosheet FET).

Typically, a top surface of a conventional backside contact receives the semiconductor device current from two adjacent semiconductor devices, which as previously discussed, causes a high I/R drop that and reduces the effective channel length (Ieff). The two top surfaces of backside contact 197 each receives the device current from a single semiconductor device reducing the I/R drop of each top surface of the merged backside contact 197. Backside contact 197 may also provide an increased Ieff and increased electrical performance of the semiconductor device. Additionally, by creating a larger contact area with BSPR 190 for backside contact 197, the electrical resistance of the connection to BSPR 190 is lower compared to a conventional backside contact with a smaller contact area with BSPR 190. In various embodiments, backside contact 197 is used for a high-performance connection to two adjacent S/D 95 contacts. The top connection of backside contact 197 is separated into two top surfaces that each connect to one S/D 95 and each of the two adjacent S/D 95 to provide current from a single GAA nanosheet FET device to a portion of the top surface of backside contact 197. Backside contact 197 merges or joins the currents from the two semiconductor devices (i.e., the two GAA nanosheet FETs) into a single connection to BSPR 190.

In a conventional semiconductor device such as a GAA nanosheet FET, the conventional cylindrical or column-like backside contacts connecting two adjacent source/drains are separated by the backside ILD and do not touch each other (i.e., the conventional backside contacts are not merged). In a conventional backside contact, the current of two semiconductor devices may go into the single backside contact creating a high insulation/resistance (I/R) drop which increases the source voltage and reduces Ieff compared to backside contact 197.

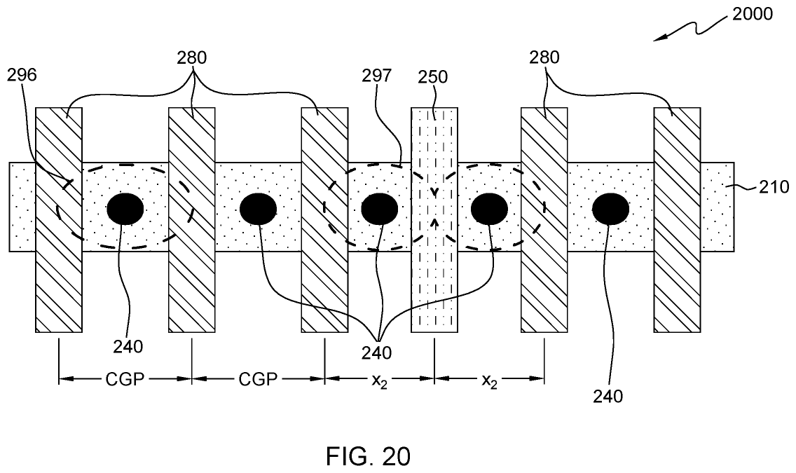

Backside contact 197 and backside contact 196 are self-aligned contacts. In some embodiments, as depicted in FIG. 20, the distance between the centers of the two adjacent dummy gates 8, labeled CGP, in FIG. 1 is less than the distance (CGP) between the other adjacent dummy gates 8 in order to ensure that backside contact 197 is a merged backside contact (e.g., a single bottom surface contacting BSPR 190 but with two top surfaces contacting to two different S/D 95).

In various embodiments, SDB 121 is in direct contact with spacers 31, channel layers 7 and inner spacers 41 where channel layers 7 and inner spacers 41 also contact one of the two adjacent S/D 95 connecting to backside contact 197. SDB 121 can be between the two adjacent S/D 95 contacting backside contact 197. SDB 121 can physically and electrically isolate the two adjacent S/D 95 connecting to backside contact 197. In an embodiment, SDB 121 is not present in semiconductor structure 1900.

FIG. 20 depicts a top view of a semiconductor design of semiconductor device 2000 with backside contact 297 and backside contact 296, in accordance with an embodiment of the present invention. As depicted, FIG. 20 includes active area 210, gates 280, SDB 250, S/D 240, backside contact 296 that is an enlarged backside contact, and backside contact 297. As illustrated, the dashed lines depict a bottom surface of backside contact 296 and backside contact 297. The area surrounded by the dashed lines labeled 296 and 297 are the bottom surfaces of backside contact 296 and backside contact 297 that contact the backside power rail (depicted in FIG. 19).

In the top view of the semiconductor design, backside contact 297 merges two top surfaces of backside contact 297 that contact with the bottom surfaces of two S/D 240 to form a large bottom surface of backside contact 297. The large bottom surface of backside contact 297 connects with the backside power rail (not depicted in FIG. 20). The shape of the bottom surface of backside contact 297 is approximately illustrated as two connecting circles in FIG. 20. The connecting or merged circles of the bottom surface of backside contact 297 as depicted in FIG. 20 creates a large contact area between backside contact 297 and the backside power rail (depicted in FIG. 19). FIG. 20 also depicts backside contact 296 connecting one of S/D 240 to the backside power rail. In other examples, the area of the bottom surface of backside contact 296 can be larger or smaller (e.g., more like a circle with a one CGP diameter or an oval). As depicted in FIG. 20, the width of the contact area of the bottom surface of backside contact 296 in the direction parallel to and approximately on the centerline of the two adjacent gates 280 of the two adjacent semiconductor devices is approximately one CGP.

Also, illustrated is a CGP distance between two of gates 280 that are adjacent to each other and the rightmost gate 280 is adjacent to SDB 250 (e.g., a single diffusion break). As depicted, FIG. 20 illustrates the distance x2 between a center of each gate 280 adjacent to SDB 250 and the center of SDB 250. In various embodiments, the CGP distance is equal to distance X2. In an embodiment, as depicted in FIG. 20, distance x2 is less than the CGP distance. Reducing distance x2 between the two adjacent gate 280 adjacent to SDB 250 ensures that the top contacting portions of backside contact 297 connect to create a single bottom surface of backside contact 297 contacting the backside power rail where the backside power rail is depicted in FIG. 19. As discussed above, the single bottom surface of backside contact 297 contacting the backside power rail forms a bottom surface area shape of backside contact 197 that is similar to two joined circles or ovals.

In various embodiments, semiconductor device 2000 can be one of a nanosheet FET, such as GAA nanosheet FET, a finFET, a complimentary FET (CFET), one or more phase change memory device, other type of semiconductor device that can have a merged backside contact. Semiconductor device 2000 in FIG. 20 includes active area 210, gates 280, S/D 240, backside contact 296 connecting to one of S/D 240, and backside contact 297 connecting to two of contacts 240. As known to one skilled in the art, active area 210 can include at least nanosheet channel layers, gate 280, and source/drains. As discussed above, merging the connection of two adjacent S/D 240 to create a single, large backside contact surface of backside contact 297 with the backside power rail can provide a high-performance connection with a reduced I/R drop.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor structure comprising:
two adjacent semiconductor devices of a plurality of semiconductor devices;
two adjacent source/drains of the two adjacent semiconductor devices; and
a backside contact connects the two adjacent source/drains of the two adjacent semiconductor devices to a backside power rail.

2. The semiconductor structure of claim 1, wherein the backside contact has a larger bottom contact area with the backside power rail than a combined area of two top surfaces of the backside contact connecting to the two adjacent source/drains.

3. The semiconductor structure of claim 1, wherein the two adjacent source/drains are electrically separated by a single diffusion barrier.

4. The semiconductor structure of claim 1, wherein the backside contact has a slope of sidewalls of the backside contact that is between 40 and 80 degrees.

5. The semiconductor structure of claim 2, wherein the backside contact has a bottom contact area width of approximately two contacted gate pitches.

6. The semiconductor structure of claim 1, wherein the backside contact has an M-shape in a cross-sectional view, and wherein the backside contact has two top surfaces.

7. The semiconductor structure of claim 6, wherein the backside contact connects two adjacent source/drains of the two adjacent semiconductor devices to the backside power rail, providing a current from the two adjacent semiconductor devices to the backside power rail, and wherein each of the two top surfaces of the backside contact connect to a source/drain of the two adjacent source/drains.

8. The semiconductor structure of claim 1, wherein the backside contact includes a portion of a semiconductor material below and between the two adjacent source/drains.

9. The semiconductor structure of claim 8, wherein the portion of the semiconductor material below and between the two adjacent source/drains contacts a bottom dielectric isolation layer under a single diffusion break.

10. The semiconductor structure of claim 1, wherein the two adjacent source/drains contact a plurality of inner spacers around a single diffusion break, and wherein the single diffusion break is between the two adjacent source/drains.

11. The semiconductor structure of claim 10, wherein a distance between each gate of the two adjacent semiconductor devices and the single diffusion break is less than the distance between each gate of the plurality of semiconductor devices adjacent to the two adjacent semiconductor devices.

12. The semiconductor structure of claim 8, wherein the portion of the semiconductor material has an upside-down, cone shape.

13. The semiconductor structure of claim 1, wherein the two adjacent source/drains have a space less than one contacted gate pitch between the two adjacent source/drains.

14. The semiconductor structure of claim 1, further comprises:
a middle-of-line contact connects a source/drain of one or more semiconductor devices of the plurality of semiconductor devices to a back-end-of-line interconnect wiring layer, wherein the source/drain resides on the bottom dielectric isolation layer;
a carrier wafer contacts the back-end-of-line interconnect wiring; and
a backside power delivery network is directly under the backside power rail.

15. A semiconductor structure comprising:
two adjacent semiconductor devices;
a source/drain connecting to the two adjacent semiconductor devices; and
a backside contact connects the source/drain to a backside power rail, wherein a bottom surface of the backside contact is larger than a top surface of the backside contact.

16. The semiconductor structure of claim 15, wherein the bottom surface of the backside contact has a width of approximately one contacted gate pitch.

17. The semiconductor structure of claim 15, wherein the backside contact has a slope of a sidewall of the backside contact that is between 40 and 80 degrees.

18. A method of forming a semiconductor structure comprising:
removing two portions of a bottom dielectric isolation layer and a top portion of a semiconductor material directly adjacent a liner covering a nanosheet stack, wherein the nanosheet stack is covered by a dummy gate;
removing a second portion of the semiconductor material to increase a diameter of a cavity in the semiconductor material, wherein the removing the second portion of the semiconductor material stops at an etch stop layer;
growing by epitaxy, a silicon-germanium material on the etch stop layer to fill the cavity in the semiconductor material;
removing the liner;
growing by epitaxy, two source/drains on the silicon-germanium material, wherein a top surface of each of the two source/drains is above a top channel layer of the nanosheet stack;
depositing an interlayer dielectric material and planarizing;
removing the dummy gate and the nanosheet stack above a portion of the bottom dielectric isolation layer;
forming single diffusion break on the portion of the bottom dielectric isolation layer;
removing a semiconductor substrate under the etch stop layer;
removing the etch stop layer;
removing the semiconductor material under the bottom dielectric isolation layer;
depositing a backside interlayer dielectric material;
removing the silicon-germanium material;
forming a backside contact contacting the two source/drains, wherein a width of a bottom surface of the backside contact is wider than a combined width of the backside contact contacting the two source/drains, and
forming a backside power rail contacting the backside contact and the backside interlayer dielectric material.

19. The method of claim 18, wherein forming the single diffusion break on the portion of the bottom dielectric isolation layer, further comprises:
removing the dummy gate and each layer of a sacrificial semiconductor material;
forming a replacement metal gate;
forming contacts to a back-end-line interconnect wiring;
attaching a carrier wafer; and
flipping the carrier wafer.

20. The method of claim 18, wherein forming the backside contact contacting the two source/drains and the backside power rail, and wherein a portion of the semiconductor material under the single diffusion break remains in the backside contact.
